(19) United States
(12) Patent Application Publication
(10) Pub. No.: US 2020/0070119 A1
(43) Pub. Date: Mar. 5, 2020

(54) SYSTEMS AND METHODS TO PERFORM CHEMICAL SYNTHESIS ON WAFERS

(71) Applicant: CENTRILLION TECHNOLOGY HOLDINGS CORPORATION, Grand Cayman (KY)

(72) Inventors: Filip CRNOGORAC, Redwood City, CA (US); Glenn McGALL, Palo Alto, CA (US); Bolan LI, Mountain View, CA (US); Wei ZHOU, Saratoga, CA (US)

(21) Appl. No.: 16/614,711

(22) PCT Filed: May 23, 2018
(86) PCT No.: PCT/US2018/034067

§ 371 Date: Nov. 18, 2019

Related U.S. Application Data
(60) Provisional application No. 62/509,840, filed on May 23, 2017.

(51) Int. Cl. B01J 19/00; G01N 21/64; H01L 21/67; G01N 21/95

(52) U.S. Cl. CPC B01J 19/0046; G01N 21/6458; B01J 2219/00722; G01N 21/9501; H01L 21/6715

(57) ABSTRACT

The present disclosure provides methods, device, and system for wafer processing. The wafer processing apparatus uses a nozzle in a lid to disperse a solution to the surface of a wafer. Further, the wafer is positioned on top of a vacuum chuck and does not spin while the solution is dispensed over the surface of the wafer via surface tension, thereby permitting the first solution to react with a reagent on the surface. Further, when dispensing the first solution, a separation gap between the lid and the wafer is at a predetermined distance, for example, from about 20 μm to about 2 mm.

### CROSS-REFERENCE

This application claims the benefit of U.S. Provisional Patent Application No. 62/509,840, filed on May 23, 2017, which is entirely incorporated herein by reference.

### BACKGROUND

Advances in materials and systems to analyze and characterize biological and biochemical materials have led to improved understanding of the mechanisms of life, health, disease and treatment. For example, genomic sequencing can be used to obtain biomedical information in diagnostics, prognostics, biotechnology, and forensics. The detection of distinctive nucleic acid sequences is critical to many endeavors including identifying microorganisms, diagnosing infectious diseases, detecting genetic abnormalities, identifying biomarker associated with various cancers, rating genetic susceptibility to selected diseases, and evaluating patient's response to medical treatments. Accordingly, oligonucleotide-based deoxyribonucleic acid (DNA) microarrays may become a useful tool for large-scale parallel analyses of genome sequence and gene expression. Current applications of DNA microarrays include global analyses of transcriptional processes, evaluation of clinical course of tumors, and accelerated discovery of drug targets. Manufacturing these oligonucleotide-based DNA microarrays may need reliable chemical synthesis on a solid surface.

### SUMMARY

The present disclosure provides methods, devices and systems for automated high throughput synthesis of chemical entities using low volume chemical reagents on a substrate, for example, in the synthesis of oligonucleotides on a wafer.

An aspect of the present disclosure provides a method for processing wafers, the method comprises: (a) dispensing a first solution onto a first surface of a first wafer by a nozzle residing in a lid; (b) spreading the first solution over the first surface; and (c) reacting the first solution with a first reagent on the first surface, thereby forming a first product; wherein the first wafer does not spin in (a)-(c).

In some embodiments of aspects provided herein, a separation gap between the lid and the first wafer ranges from about 20 μm to about 2 mm. In some embodiments of aspects provided herein, the forming a first product in (c) comprises forming a covalent bond within a reaction chamber defined by the separation gap. In some embodiments of the aspect provided herein, in (b) the spreading substantially fills the reaction chamber with the first solution. In some embodiments of aspects provided herein, the first solution comprises a first chemical reagent and a second chemical reagent. In some embodiments of aspects provided herein, the first solution comprises a phosphorylating reagent.

In some embodiments of aspects provided herein, the method further comprises, after (c): (d) dispensing a second solution onto the first surface by the nozzle, thereby spreading the second solution over the first surface and forming a second product with a second reagent on the first surface; wherein the first wafer does not spin in (d). In some embodiments of aspects provided herein, the second reagent is the first product. In some embodiments of aspects provided herein, the second solution comprises a third chemical reagent and a fourth chemical reagent.

In some embodiments of aspects provided herein, the method further comprises after (c): (d) dispersing a gas onto the first surface, wherein the first wafer does not spin in (d). In some embodiments of aspects provided herein, the gas is an inert gas. In some embodiments of aspects provided herein, the gas is dispersed from the nozzle.

In some embodiments of aspects provided herein, the efficiency of the reaction between the first solution and the first reagent in (c) is higher than a corresponding reaction in a flow-cell. In some embodiments of aspects provided herein, the uniformity of the reaction between the first solution and the first reagent in (c) is better than a corresponding reaction in a flow-cell.

In some embodiments of aspects provided herein, the method further comprises prior to (a): (i) moving the first wafer from a first position to a second position by a wafer conveyance robot; and (ii) placing the first wafer on top of a vacuum chuck at the second position. In some embodiments of aspects provided herein, the method further comprises adjusting support columns of the lid, thereby making a bottom surface of the lid and the first surface of the first wafer substantially parallel. In some embodiments of aspects provided herein, the moving in (i) comprises removing the first wafer from a wafer cassette at the first position. In some embodiments of aspects provided herein, the wafer cassette is configured to hold at least another wafer. In some embodiments of aspects provided herein, the method further comprises enclosing the first wafer, the nozzle and the lid within an inert gas chamber.

In some embodiments of aspects provided herein, the first reagent is a functional group bounded to the first surface. In some embodiments of aspects provided herein, the functional group is hydroxyl group, amino group, carbonyl group, or carboxyl derivative group.

In some embodiments of aspects provided herein, the method further comprises after (c): (d) removing the first wafer from the second position; (e) moving a second wafer from the first position to the second position by the wafer conveyance robot; and (f) placing the second wafer on top of the vacuum chuck at the second position. In some embodiments of aspects provided herein, the method further comprises after (f): (g) dispensing a third solution onto a second surface of the second wafer by the nozzle, spreading the third solution over the second surface, reacting with a third reagent on the second surface, and forming a third product; wherein the second wafer does not spin in (g).

Additional aspects and advantages of the present disclosure will become readily apparent to those skilled in this art from the following detailed description, wherein only illustrative embodiments of the present disclosure are shown and described. As will be realized, the present disclosure is capable of other and different embodiments, and its several details are capable of modifications in various obvious respects, all without departing from the disclosure. Accordingly, the drawings and description are to be regarded as illustrative in nature, and not as restrictive.

### INCORPORATION BY REFERENCE

All publications, patents, and patent applications mentioned in this specification are herein incorporated by reference to the same extent as if each individual publication, patent, or patent application was specifically and individually indicated to be incorporated by reference.

### BRIEF DESCRIPTION OF THE DRAWINGS

The novel features of the invention are set forth with particularity in the appended claims. A better understanding of the features and advantages of the present invention will be obtained by reference to the following detailed description that sets forth illustrative embodiments, in which the principles of the invention are utilized, and the accompanying drawings of which:

FIG. 1 is a perspective view of a wafer processing apparatus 100 as the embodiment of the present disclosure.

FIG. 2 depicts a partial perspective view of the reaction assembly 200 of a wafer processing apparatus as the embodiment of the present disclosure.

FIG. 3 shows a partial sectional view of the reaction assembly 300 of a wafer processing apparatus as the embodiment of the present disclosure.

FIG. 4 illustrates an example image analysis of fluorescent signals from wafers obtained by a method disclosed in the present disclosure.

FIG. 5 is an example graph of fluorescent signals recorded in one image using the image analysis method illustrated in FIG. 4.

FIG. 6 is a bar graph to compare fluorescent signals recorded using the device/system/method of the present disclosure and those recorded using a flow-cell.

### DETAILED DESCRIPTION

While various embodiments of the invention have been shown and described herein, it will be obvious to those skilled in the art that such embodiments are provided by way of example only. Numerous variations, changes, and substitutions may occur to those skilled in the art without departing from the invention. It should be understood that various alternatives to the embodiments of the invention described herein may be employed.

DNA sequence microarrays or DNA chips have become a useful tool in biological and biomedical sciences to understand the correlation of gene sequences with their functions. In some cases, DNA chips containing surface-bound oligonucleotides or probes are used to interrogate target nucleic acid sequences via hybridization.

Current methods to fabricate deoxyribonucleic acid (DNA) microarray include spot DNA onto nylon membranes or glass slides by robots with pins or ink jet printers. This usually involves naturally available DNA molecules or fragments thereof. When the require DNA sequences are not naturally available, oligonucleotides may be synthesized de novo on the solid surface of the array in a controlled manner. A system, device and method to synthesize non-natural or natural DNA sequences on DNA chips that are easy to manufacture with high fidelity in synthesized DNA probes on the surface are desirable. Accordingly, new system and methods to allow controlled chemical synthesis on a solid surface are of interest in the biomedical and biopharmaceutical field.

Microarrays of de novo synthesized oligonucleotides offer a number of advantages over other types of DNA microarrays, including (i) more controlled specificity of hybridization, which makes them particularly useful for the analysis of single nucleotide polymorphisms or mutational analysis; (ii) versatility to address questions about transcriptome composition such as the presence and prevalence of alternatively spliced or alternatively polyadenylated transcripts; (iii) capacity to systematically screen whole genomic regions for gene discovery; and (iv) ability to generate sequence information independent of biological samples when manufacturing custom-made microarrays.

However, manufacturing custom-made oligonucleotides microarrays may require inert and controlled environment due to the presence of air- and/or moisture-sensitive reagents in oligonucleotide synthesis. Further, chemical synthesis on a solid surface may require the use of large quantity of such air- and/or moisture-sensitive reagents, which may increase the cost of the manufacture or prolong the average turnover time for the manufacture of wafers. Finally, because oligonucleotide synthesis requires the repetition of similar synthetic manipulations with different reagents, contamination by reagent leftovers may present a problem.

After much effort in experimentation, Applicants have found a new system and method for the fabrication of wafers with de novo synthesis of oligonucleotides. In addition, the new system and method may allow automated high throughput manufacturing of wafers involving reduced volume/amount of chemical reagents.

As used herein, the singular forms “a”, “an”, and “the” include plural references unless the context clearly dictates otherwise.

The term “fragment” as used herein generally refers to a fraction of the original DNA sequence or RNA sequence of the particular region.

The term “nucleotide,” as used herein, generally refers a molecule that can serve as the monomer, or subunit, of a nucleic acid, such as deoxyribonucleic acid (DNA) or ribonucleic acid RNA). A nucleotide can be a deoxynucleotide triphosphate (dNTP) or an analog thereof, e.g., a molecule having a plurality of phosphates in a phosphate chain, such as 2, 3, 4, 5, 6, 7, 8, 9, or 10 phosphates. A nucleotide can generally include adenosine (A), cytosine (C), guanine (G), thymine (T) and uracil (U), or variants thereof. A nucleotide can include any subunit that can be incorporated into a growing nucleic acid strand. Such subunit can be an A, C, G, T, or U, or any other subunit that is specific to one or more complementary A, C, G, T or U, or complementary to a purine (i.e., A or G, or variant thereof) or a pyrimidine (i.e., C, T or U, or variant thereof). A subunit can enable individual nucleic acid bases or groups of bases (e.g., AA, TA, AT, GC, CG, CT, TC, GT, TG, AC, CA, or uracil-counterparts thereof) to be resolved. A nucleotide may be labeled or unlabeled. A labeled nucleotide may yield a detectable signal, such as an optical, electrostatic or electrochemical signal.

The term “about” or “nearly” as used herein generally refers to within +/−15%, 10%, 9%, 8%, 7%, 6%, 5%, 4%, 3%, 2%, or 1% of the designated amount.

All words of approximation as used herein should be construed to mean “approximate,” rather than “perfect,” and may accordingly be employed as a meaningful modifier to any other word, specified parameter, quantity, quality, or concept. Words of approximation, include, yet are not limited to terms such as “substantial”, “nearly”, “almost”, “about”, “generally”, “largely”, “essentially”, “substantially”, “closely approximate”, etc. For example, the term “substantially” includes “reasonably close to: nearly, almost, about”, connoting a term of approximation. When describing filling the reaction chamber with a solution or reagent in the present disclosure, the phrase “substantially fill the reaction chamber” generally refers to fill at least 90%, at least 91%, at least 92%, at least 93%, at least 94%, at least 95%, at least 96%, at least 97%, at least 98%, or at least 99% of the volume of the reaction chamber.

As used herein, the terms “polynucleotide”, “oligonucleotide”, “nucleotide”, “nucleic acid” and “nucleic acid molecule” generally refer to a polymeric form of nucleotides (polynucleotides) of various lengths, either ribonucleotides (RNA) or deoxyribonucleotides (DNA). Examples of nucleotide sequences are sequences corresponding to natural or synthetic RNA or DNA including genomic DNA and messenger RNA. The length of the sequence can be any length that can be amplified into nucleic acid amplification products, or amplicons, for example, up to about 20, 50, 100, 200, 300, 400, 500, 600, 700, 800, 1,000, 1,200, 1,500, 2,000, 5,000, 10,000 or more than 10,000 nucleotides in length, or at least about 20, 50, 100, 200, 300, 400, 500, 600, 700, 800, 1,000, 1,200, 1,500, 2,000, 5,000, 10,000 or 10,000 nucleotides in length.

The term “array” as used herein, when describing a device, a system, sensors, sample chambers, etc., generally refers to a one-dimensional or two-dimensional set of microstructures. An array may be any shape. For example, an array may be a series of microstructures arranged in a line, such as the array of squares. An array may be arranged in a square or rectangular grid. There may be sections of the array that are separated from other sections of the array by spaces. An array may have other shapes. For example, an array may be a series of microstructures arranged in a series of concentric circles, in a series of concentric squares, a series of concentric triangles, a series of curves, etc. The spacing between sections of an array or between microstructures in any array may be regular or may be different between particular sections or between particular pairs of microstructures. The microstructure arrays of the present disclosure may be comprised of microstructures having zero-dimensional, one-dimensional or two-dimensional shapes. The microstructures having two-dimensional shapes may have shapes such as squares, rectangles, circles, parallelograms, pentagons, hexagons, irregular shapes, etc.

The terms “plate” and “substrate” as used herein generally refer to the solid portion of an apparatus whose surface is used to synthesize oligonucleotides or conduct chemical reactions.

A characteristic of a “thin-film,” as disclosed herein generally refers to that a layer of mobile phase, solution or liquid is spread over a surface of a plate through the action of surface tension, and/or adhesion to the surface of the plate. In some cases, a thin film is a liquid sample in which the diffusion time is no more than about four-fold greater, no more than about three-fold greater, no more than about two-fold greater, no more than about one-fold greater in one dimension than that in any other dimension. In some cases, the temperature conductance characteristics of a thin film sample are no more than about four-fold greater, no more than about three-fold greater, no more than about two-fold greater, no more than about one-fold greater in one dimension than that in any other dimension.

The term “processor” as used herein generally refers to a personal computer with associated memory. The processor would have sufficient transient RAM memory, non-transient storage memory, processing power, and hardware, such as interface cards to run the associated control software, interface with and operate the automated components of the apparatus, such as the various pumps, motors, valves, sensors, and detectors, and record the values from the sensors, probes and detectors.

The term “wafer” as used herein generally refers to a plate, substrate, or semiconductor chip. The wafer may be circular. The diameter of a wafer can be, for example, about 50 mm, about 100 mm, about 150 mm, about 200 mm, about 250 mm, or other lengths. In addition, the wafer may comprise a layer of SiO₂ on its surface. The thickness of the SiO₂ layer may be about 20 nm, about 30 nm, about 40 nm, about 50 nm, about 55 nm, about 60 nm, about 65 nm, about 70 nm, about 75 nm, about 80 nm, about 100 nm, and more than 100 nm. The wafer may comprise an organic polymer layer on its surface. The wafer may comprise surface hydroxyl groups for attachment or reactions.

The term “carboxyl derivative” as used herein generally refers to functional groups that comprise acyl group and can form ester or amide bonds with another reagent comprising hydroxyl or amino groups. Examples of carboxyl derivative include carboxylic acid, acyl halide, anhydride, ester, thioester, and acyl phosphate.

The term “phosphorylating reagent” as used herein generally refers to a chemical reagent or a mixture of chemical reagents that are capable of introducing a phosphate group or a phosphite group into another molecule. An example of a phosphorylating reagent is a phosphoramidite reagent, which can react with a nucleoside monomer or oligonucleotide that comprises a hydroxyl group to give a phosphorous acid trimester what is subsequently oxidized to a phosphoric acid trimester of the nucleoside monomer or oligonucleotide.

Devices and Methods

The present disclosure provides methods, devices, and systems to enable fabrication of an array of oligonucleotide or other organic molecules on the surface of a plate. The methods, device, and systems of the present disclosure can comprise components including, but not limited to:

1. Wafer cassette, which can hold a plurality of wafers. Wafers can be placed into and out of the wafer cassette.

2. Wafer conveyance robot, which can retrieve a specific wafer from a first wafer cassette, transfer the wafer to at least one pre-determined location; and place the wafer to a second wafer cassette or the first wafer, depending on the needs. The wafer conveyance robot may comprise at least one motor, at least one movable arm, and a wafer holder attached to the end of one arm. The wafer conveyance robot can move horizontally and vertically with the help of the motor(s).

3. Vacuum chuck, which can be a vacuum suction type to secure a wafer during the chemical synthesis. It may comprise at least two side arms, at least three side arms, or at least four side arms to facilitate the positioning of the wafer on top of the vacuum chuck. The vacuum chuck may not be limited as long as the chuck can vacuum-suck and hold an object to be sucked and held via a mechanism of a vacuum pump.

4. Lid, which can be raised or lowered to a specific height by a motor. The lid may have at least one supporting column connected to either the motor or an arm controlled by the motor. The at least one supporting column may be adjusted manually or mechanically so that the lid can adopt selected positions relative to the wafer lying below. The lid may be in a disk shape. The bottom face of the lid may be facing the top surface of the wafer on the vacuum chuck and may substantially cover the top surface of the wafer when the lid is lowered. The lid may align with the wafer along a vertical axis at the center of and perpendicular to the surface of the wafer. In the middle of the lid may be a nozzle for controlled delivery of solutions or reagents to the top surface of the wafer. The reagents may be in solution, liquid or gas forms. The delivery of solutions/reagents may be facilitated by compressed air or a pump. The amount and sequence of solutions/reagents to be delivery as well as the rate of delivery may be controlled by an external controller, for example, a computer or a microprocessor. The wafer processing apparatus can further comprise a plurality of containers for holding the solutions/reagents, wherein the nozzle is in flow communication and operatively associated with each container such that the nozzle can selectively and sequentially dispense an amount of a reagent/solution. The solutions/reagents can be transferred to the nozzle via a conduit or tube on top of the lid. The nozzle can blow a gas (i.e., air, nitrogen, other inert gases, or a mixture of inert gases) in-between the lid and the top surface of the substrate, thereby, removing excess reagents remaining on the surface of the substrate by pushing the reagents off the edge of the substrate, drying the top surface and/or separating the bottom surface of the lid from the top surface of the substrate. The diameter of the lid may be about the diameter of the wafer it covers, longer than the diameter of the wafer, or shorter than the diameter of the wafer.

6. Reaction chamber, which is the space between the lower surface of the lid and the top surface of the wafer, or the space of the “gap”. The term “gap” as used herein generally refers to the substantially cylindrical space enclosed by the lower surface of the lid, the top surface of the wafer, and an imaginary curved side defined by the circumferences of the lower surface of the lid and the top surface of the wafer. The gap distance may be the vertical distance between the bottom surface of the lid and the top surface of the wafer. The gap distance can be controlled by adjusting the at least one supporting column and the gap distance may range from about 20 μm to about 2.0 mm. The gap distance may be about 20 μm, about 30 μm, about 40 μm, about 50 μm, about 60 μm, about 70 μm, about 80 μm, about 90 μm, about 100 μm, about 110 μm, about 120 μm, about 130 μm, about 140 μm, about 150 μm, about 160 μm, about 170 μm, about 180 μm, about 190 μm, about 200 μm, about 210 μm, about 220 μm, about 230 μm, about 240 μm, about 250 μm, about 260 μm, about 270 μm, about 280 μm, about 290 μm, about 300 μm, about 400 μm, about 500 μm, about 600 μm, about 700 μm, about 800 μm, about 900 μm, about 1 mm, about 1.1 mm, about 1.2 mm, about 1.3 mm, about 1.4 mm, about 1.5 mm, about 1.6 mm, about 1.7 mm, about 1.8 mm, about 1.9 mm, about 2.0 mm.

The reaction chamber may be semi-enclosed due to the small gap distance between the two aforementioned surfaces. The gap distance can be controlled to allow the spreading and mixing of a solution delivered via the nozzle in the lid. For example, if the gap distance is too large, solutions/reagents dispersed on the surface of the wafer may flow off the surface due to the gravity of the solutions/reagents. On the other hand, if the gap distance is too small, there may not be enough volume for the surface reactions to occur or may slow down the speed of the spread of the reagents/solutions. The concentrations of the reagents dispersed can be varied according to the volume of the reaction chamber chosen. The reaction chamber can comprise an aqueous or organic environment in which a plurality of reagents introduced from the nozzle may be present. The plurality of reagents may react with each other or react with intermediate products formed by previous reactions. For example, a reagent newly delivered onto the surface of the wafer may react with functional groups attached to the surface of the wafer. A reagent newly delivered may react with previously delivered reagent(s) staying on the surface of the wafer. Optionally, the lid, the wafer and the vacuum chuck are placed inside a controlled atmosphere chamber or an inert atmosphere chamber filled with inert gas, such as, for example, nitrogen, argon or another noble gas, or mixture thereof. In addition, the controlled atmosphere chamber or the inert atmosphere chamber may have an inlet for the inert gas and an outlet for the inert gas so that a constant air flow may be maintained within the controlled atmosphere chamber to enclose the reaction chamber, so that air-sensitive or moisture sensitive reaction may occur in the reaction chamber.

In addition, the device may comprise a computer system to control, for example, the delivery of the reagents, the movement of parts of the device, and other operation of the device.

The components of the apparatus can be made from stainless steel, aluminum, non-ferrous alloys, Teflon®, high density poly ethylene (HDPE), or any other material understood by those of ordinary skill in the art for use in particular applications that may depend on the solution acidity or alkalinity, salinity, temperature, or other chemical or physical properties, as well as the ability to prevent contamination and be properly cleaned between chemical reactions.

Methods, devices, and systems of the present disclosure can employ variants of the above components assembled together to create a system capable of manufacture wafers and conducting surface chemistry on the surface of the wafers.

General Methods

The present disclosure employs, unless otherwise indicated, conventional techniques in photolithography, chemical etching, general machining, microfluidics, organic chemistry, biochemistry, oligonucleotide synthesis and modification, nucleic acid hybridization, molecular biology, microbiology, genetic analysis, recombinant DNA, and related fields as are within the skill of the art. These techniques are described in the references cited herein and are fully explained in the literature. See, for example, Maniatis, Fritsch & Sambrook, MOLECULAR CLONING: A LABORATORY MANUAL, Cold Spring Harbor Laboratory Press (1982); Sambrook, Fritsch & Maniatis, MOLECULAR CLONING: A LABORATORY MANUAL, Second Edition, Cold Spring Harbor Laboratory Press (1989); Ausubel, et al., CURRENT PROTOCOLS IN MOLECULAR BIOLOGY, John Wiley & Sons (1987 and annual updates); Gait (ed.), OLIGONUCLEOTIDE SYNTHESIS: A PRACTICAL APPROACH, IRL Press (1984); Eckstein (ed.), OLIGONUCLEOTIDES AND ANALOGUES: A PRACTICAL APPROACH, IRL Press (1991); Birren et al. (eds.) GENOME ANALYSIS: A LABORATORY MANUAL, Cold Spring Harbor Laboratory Press, 1999.

### EXAMPLES

The system and method of a wafer processing apparatus according to the present disclosure will be described below with reference to the drawings.

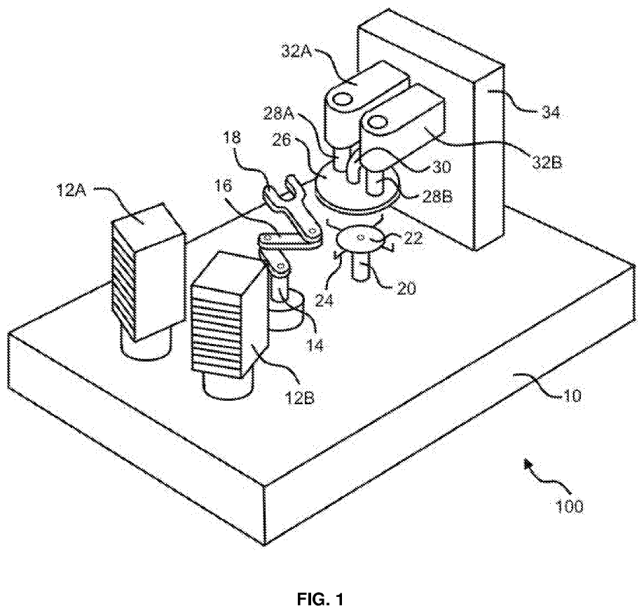

FIG. 1 is a perspective diagram showing the general structures of a wafer processing apparatus 100 according to a first embodiment of the present disclosure. In FIG. 1, a wafer conveyance robot 16 may compose a first robot mechanism 14 and a wafer holder 18. The wafer conveyance robot 16 may be on a polar coordinate system and disposed on an upper surface of a base 10. Wafer cassettes 12A and 12B, and a vacuum chuck 22 may be disposed radially around the wafer conveyance robot 16. The wafer cassettes 12A and 12B, and the vacuum chuck 22 may be arranged within a range in which a wafer can be brought into and out of the wafer cassettes 12A and 12B by the wafer conveyance robot 16, and placed on the top of the vacuum chuck 22.

The wafer cassettes 12A and 12B may accommodate a plurality of wafers before and after wafer processing. The first robot mechanism 14 can move vertically and horizontally so that a wafer can be brought into and out of the wafer cassettes 12A and 12B by the wafer conveyance robot 16, and be placed on the top of the vacuum chuck 22. The vacuum chuck 22 may comprise side arms 24 so that when a wafer is placed on top of the vacuum chuck 22 by the wafer holder 18, the wafer may be centered on the vacuum chuck 22. A vacuum applied via the vacuum chuck 22 may hold the wafer in place and force the wafer move together with the moving vacuum chuck 22. The vacuum chuck 22 may be positioned on top of a supporting shaft 20. The supporting shaft may optionally move vertically to adjust the height of the wafer.

Directly above the vacuum chuck 22 may be a lid 26. The lid 26 may be in a flat disk shape. The bottom surface of the lid 26 may face the top surface of the wafer on the vacuum chuck 22 and may substantially cover the top surface of the wafer when the lid 26 is lowered into the position for conducting chemical synthesis. In some cases, the lid 26 may align with the wafer along a vertical axis at the center of and perpendicular to the surface of the wafer. The wafer may be circular. In some cases, there may be two supporting columns 28A and 28B holding the lid 26. In other cases, more than two supporting columns 28 may hold the lid 26. The two supporting columns 28A and 28B may be connected with a wall portion 34 via side arms 32A and 32B, respectively. The side arms 32A and 32B can move vertically and/or horizontally with the help of robot(s)/motor(s).

The operation of the wafer processing apparatus may start with the removal of one wafer from the wafer cassette 12A by the wafer conveyance robot 16 via the wafer holder 18. Then the wafer conveyance robot 16 may place the wafer on top of the vacuum chuck 22. Vacuum may be applied to the bottom surface of the wafer which may be suction-adhered to the vacuum chuck 22. After the wafer is secured on the vacuum chuck, steps to conduct chemical synthesis on the top surface of the wafer may start in the reaction chamber.

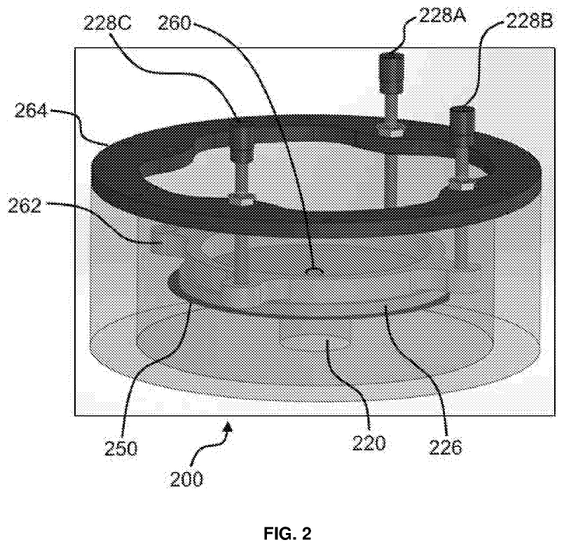

Turning now to FIG. 2, a partial, perspective graphical depiction of a reaction assembly 200 is illustrated according to another embodiment of the present disclosure. A lid 226 may be movable by supporting columns 228A, 228B and 228C vertically or horizontally, and, optionally, may be movable on the horizontal plane via a motor. In some cases, the supporting columns 228 may be adjustment screws. The lid 226 may be transparent so that a naked eye or an instrument may inspect a wafer 250 directly below the lid 226. The wafer 250 may sit on a vacuum chuck (not shown). The vacuum chuck may be configured to support and secure the wafer 250. The vacuum chuck may engage with a shaft 220 which may move the vacuum chuck vertically. As shown in FIG. 2, the lid 226 aligns with the wafer 250 along a vertical axis at the center of and perpendicular to the surface of the wafer 250. The wafer 250 and the bottom surface of the lid 226 are circular. In the center of the lid 226 there may be a hole 260, through which a nozzle and/or an inlet tube can be inserted so that to dispense at least one reagent or solution over the top surface of the wafer 250 in a controlled manner. In addition, a first hanging frame 262 may engage with both the supporting columns 228 and the lid 226. A second hanging frame 264 may engage with secure the supporting columns 228.

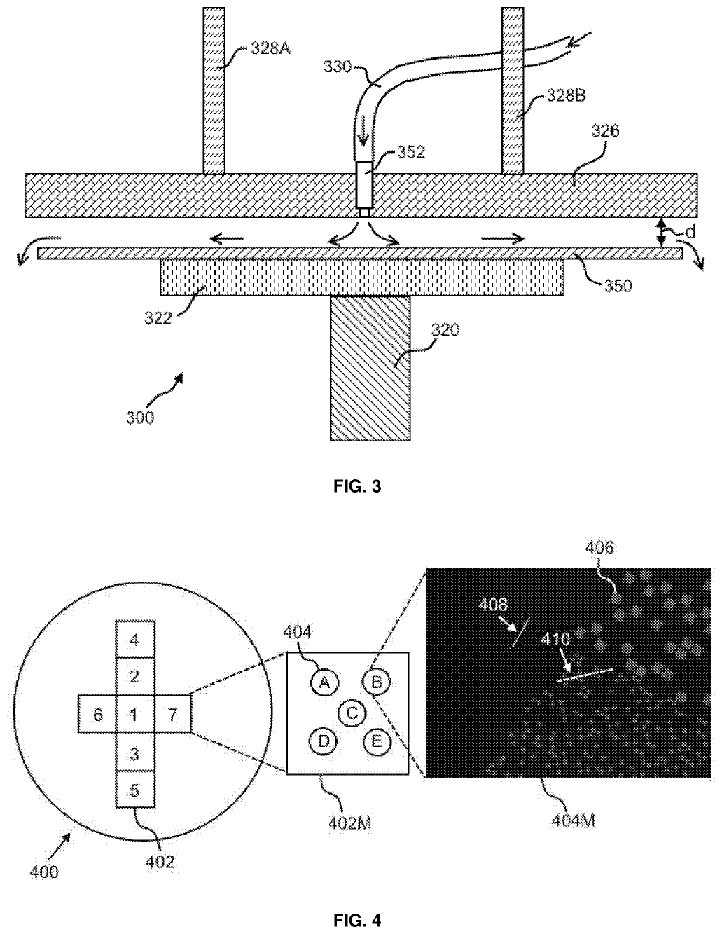

Referring to FIG. 3, the relative layout of the lid and the vacuum chuck is further depicted as reaction assembly 300 according to another embodiment of the present disclosure. In the center of a lid 326 there may be a nozzle 352 for controlled delivery of reagents to the top surface of a wafer 350, which is supported and secured by a vacuum chuck 322. The lid 326 may be movable with the help of supporting columns 328A and 328B vertically, and optionally movable on the horizontal plane via another motor. The vacuum chuck 322 may sit on and controlled by a supporting shaft 320.

The reagents can be transferred to the nozzle 352 via a conduit or tube 330 on the top of the lid 326 when the wafer 350 does not spin or when the wafer 350 remains stationary relative to the lid 326. The conduit or tube 330 can transfer gas, liquid or solution at a predetermined rate and in a predetermined amount. The conduit or tube 330 may be washed or gas dried in-between different deliveries of reagents so that contamination of reagents within the conduit or tube 330 can be reduced. The delivery of reagents may be air-propelled or pump-controlled. The amount and sequence of reagents to be delivery as well as the rate of delivery may be controlled by an external controller, for example, a computer or a microprocessor.

When gas is used to deliver the reagents, the gas may be inert gas, such as, for example, nitrogen, argon or another noble gas, or mixture thereof. Other added advantages of using inert gas to deliver reagents may include drying of the conduit or tube 330 between deliveries using the passage of inert gas; protection of air- or moisture-sensitive reagents during delivery; maintaining a positive pressure of inert gas over the top surface of the wafer 350 during chemical synthesis; and removing excess reagents from the surface of the wafer 350 at the end of the chemical reactions, either by evaporation or by pushing the reagents over the edge of the wafer 350. When gas purges over the surface of the wafer 350, the wafer 350 does not spin or the wafer 350 can remain stationary relative to the lid 326.

When the lid 326 is lowered, the gap distance d between the bottom surface of the lid 326 and the top surface of the wafer 350 can be controlled. The gap distance d between the top surface of the wafer 350 and the bottom surface of the lid 326 may range from about 20 μm to about 2 mm. The diameter of the lid 326 may be the same as the diameter of the wafer 350 it covers, longer than the diameter of the wafer 350, or shorter than the diameter of the wafer 350. In some cases, the diameter of the lid 326 may be longer than the diameter of the wafer 350. The diameter of the wafer 350 can be, for example, about 50 mm, about 100 mm, about 150 mm, about 200 mm, about 250 mm, or other lengths.

Reagents in the forms of gas, liquid or solution may be introduced into the conduit or tube 330 in a controlled manner. The nozzle 352 may deliver the reagents onto the top surface of the wafer 350 when the wafer 350 does not spin or when the wafer 350 is stationary relative to the lid 326. Liquid reagents may spread by capillary action or surface tension when the wafer 350 does not spin or when the wafer 350 is stationary relative to the lid 326. The amount of reagents delivered can be calculated or estimated based on the volume of the reaction chamber or the volume of the gap, each of which may depends on the gap distance. When describing filling the reaction chamber with a solution or reagent in the present disclosure, the phrase “substantially fill the reaction chamber” generally refers to fill at least 90%, at least 91%, at least 92%, at least 93%, at least 94%, at least 95%, at least 96%, at least 97%, at least 98%, or at least 99% of the volume of the reaction chamber. One benefit of substantially filling the reaction chamber may be to reduce the dead volume of air/gas in the reaction chamber during the reaction phase on the surface of the wafer such that unwanted side reactions, such as, for example, reactions with oxygen or moisture, may be controlled or avoided. In other words, “substantially filling the reaction chamber” may reduce the effect of the above side-reaction under an acceptable level, depending on the type of reactions and side reactions, and the requirement for the products on the wafer.

After the reaction chamber has been substantially filled with a first solution/reagent or completely filled with the first solution/reagent, the wafer 350 may remain stationary for at least 30 seconds, at least 40 seconds, at least 50 seconds, at least 60 seconds, at least 70 seconds, at least 80 second, at least 90 seconds, at least 100 seconds, at least 120 seconds, at least 3 minutes, at least 4 minutes, at least 5 minutes, or longer, to allow the solution/reagent to react with each other or other products formed previously in the reaction chamber before the start of the next delivery of a second solution/reagent. The delivered solution/reagent may form a substantially flat surface, e.g., forming a thin-film. The series of arrows with thin arrowheads in FIG. 3 may show the general direction of the reagents in the conduit or tube 330 and the nozzle 352, and the directions of the reagent's flowing patterns once delivered onto the top surface of the wafer 350 due to capillary force or surface tension. In some cases, the solution delivered may comprise one reagent. In other cases, the solution delivered may comprise at least two reagents.

After the chemical processing of the wafer is completed, the wafer may be dried by continuous inert air flow. When the wafer is considered dry enough, turning back to FIG. 1, the vacuum applied by the vacuum chuck 22 may be relieved. Then the wafer conveyance robot 16 may remove the processed wafer from the top of the vacuum chuck 22 to the inside of wafer cassette 12B for storage. Finally, the wafer conveyance robot 16 may be ready to remove another wafer from wafer cassette 12A for another round of wafer processing.

As shown and explained above, a robotically operated system has been disclosed to achieve automated high-throughput fabrication of wafers with minimal user intervention according the methods disclosed. Alternatively, the wafer conveyance robot may be replaced with a wafer track for wafer transferring tasks.

Further, an independently controlled chemical delivery system via the lid may be used to deliver different chemical solutions/reagents onto the center of the surface of the wafer. Excessive heat or gaseous by-products of the surface reactions may be dispersed by a continuous flow of inert gas either through the chemical delivery system or via a separate gas inlet/outlet system.

In one embodiment, the lid may have about the same diameter as the wafer below the lid so that the bottom surface of the lid and the top surface of the wafer may form a semi-enclosed reaction chamber in-between the two surfaces. Chemical reactions may happen in this semi-enclosed reaction chamber. In FIG. 3, the gap distance between the two surfaces may be represented by the symbol “d”. The volume of the reaction chamber may be estimated by the surface area of the wafer times the separation gap between the two surfaces: Volume=A_{wafer}×d_{gap}, wherein A_{wafer} may be the surface area of the wafer, and d_{gap} may be the gap distance between the two surfaces. This Volume can be considered as, approximately, the volume of reagents in the chemical process over the surface of the wafer because the wafer can accommodate such a volume of each solution/reagent added, according to the present disclosure. For example, if the diameter of the wafer is about 150 mm and the separation gap is about 0.5 mm, the volume of the semi-enclosed reaction chamber may be about 8 mL. This volume of the reaction chamber may be a reduction in reagent volume when compared with puddle drop systems used for polymer resist development. In the puddle drop systems, the volume of reagent used may be determined by the meniscus caused by surface tension. Moreover, if reagents used are volatile or sensitive to ambient air or moisture, for example, when phosphoramidite reagents are used, the semi-enclosed reaction chamber according to the present disclosure may minimize evaporation and reduce contamination because the outer edge of the thin film layer of the solutions/reagents in the reaction chamber on top of the wafer may be in contact with ambient air or inert gas, but other surfaces of the reagents/solutions may not be in contact with ambient air or inert gas. The exposed surface of the reagent may be: Area of exposure=π×d_{wafer}×d_{gap}, wherein d_{wafer} is the diameter of the wafer. The Area of exposure may be significantly smaller than that when no lid or cover stays close to the wafer since the top surface of the thin film on the wafer of the present disclosure may not be exposed to ambient air when the lid of the present disclosure is present.

In some cases, the reagents dispensed on the surface of the wafer may permeate the reaction chamber and cover the surface of the wafer by capillary action or surface tension, thereby improving uniformity of distribution of the reagents across the surface of the wafer. In addition, the movement of liquid against a stationary bottom surface of the lid can provide some reagent mixing. Alternatively, relief patterns can be implemented on the bottom surface of the lid, or ultrasonic module(s) can be added to the reaction chamber, so that reagent mixing can be improved.

The degree of uniformity of distribution of reagents over the top surface of the wafer may be of key importance to the quality of the wafer after the chemical processing. The degree of uniformity of distribution of the reagents may relate to various factors, wherein, to some extent, the structure of the device enclosing the reaction chamber may determine the uniformity of distribution. For example, for the reaction chamber disclosed in the present disclosure, if the bottom surface of the lid and the top surface of the wafer are kept substantially parallel and the solution of more than two reagent has been thoroughly mixed before dispensed on to the top surface of the wafer, the degree of uniformity of distribution may be high because the reaction chamber thus formed, may be completely filled with a solution which comprises reagents uniformly mixed before reaching the nozzle in the lid. Due to the small volume of the reaction chamber and the presence of surface tension/capillary effect associated with the dispersed solutions/agents, the solutions/reagents once dispersed on the top surface of the wafer may spread laterally in the radial direction of the wafer, thereby realizing the uniform distribution of the solutions/reagents over the top surface of the wafer.

In addition, uniformly distributed reagents may enhance the efficiency of reactions between the distributed reagents. For example, when several reactions in sequence are required in chemical processing of the wafer, the overall yield of the reactions may rely on or be influenced by the uniformity of distribution of reagents in each step. A non-uniformed distribution of reagents may lead to waste of reagents in the sense that one reagent may be locally more concentrated or more diluted than another reagent so that each reagent may have a fraction thereof remaining unreacted in the end. These unreacted reagents in each step may produce low overall yield for the chemical process.

Further, because the wafer remains stationary relative to the lid when the solutions/reagents are dispensed over the top surface of the wafer, the force pushing the solutions/reagents over the edge of the wafer may be the addition of more solutions/reagents via the nozzle. When the nozzle stops dispensing solutions/reagents, there may be no force from the center of the wafer to push the solutions/reagents near the edge outward. Gravity may cause some material loss near the edge. But surface tension may keep the solutions/reagents remain in the reaction chamber due to the small size of the gap distance of the reaction chamber. As a result, there may require/use less solutions/reagents because the “wasted” faction of solutions/reagents that may be pushed over the edge of the wafer may be less in the present disclosure when compare with other procedures. Moreover, the device/system of the present disclosure may be fully automated by using a processor or computer to control the moving of the wafer and the dispensing of solutions/reagents, etc. These characteristics may be advantageous over other devices/systems/methods, such as, for example, chemical synthesis in a flow-cell reactor, which allows solution/reagents to flow through the corresponding reaction chamber, or chemical synthesis on a microwell microarray plate, which requires the construction of microwell on the plate before the DNA synthesis.

In some cases, there may not be outlet port for the delivered chemicals. Excess chemicals can be pushed off the edge by the delivery of the next chemical reagent, pushed through by a puff of a processing inert gas, or any combination of the above methods. Further, process optimization to control the volume of reaction added or vacuum chuck design with a chemical waste collection portion underneath the vacuum chuck can prevent used or discarded chemicals from dripping onto the bottom surface of the wafer. In addition, additional outlet(s) may be added at the base 10 in FIG. 1 to remove spun-off or discarded chemicals. Similarly, at the completion of the wafer processing, the wafer can be inert-gas dried with a wider, pre-determined separation gap between the two surfaces, dried at an elevated temperature, or a combination of the above. Alternatively, an outlet tube can be inserted into the lid away from the nozzle and the tube (i.e. the inlet tube to deliver reagents) connected to the nozzle. The outlet tube may be configured to suck up excess reagents, used up reagents, or reagents remained in liquid forms in a controlled manner (for example, after a predetermined time of reacting) and transport the sucked-up reagents to a waste container. For example, vacuum can be applied to the outlet tube in the lid to suck up reagents. Then the next reagent can be delivered via the inlet tube in the lid and the nozzle to fill the reaction chamber.

In some cases, the lid can be cleaned with a flow of wash solution/solvent through the separation gap prior to drying of the bottom surface of the lid or the addition of solutions/reagents for the next step. This may ensure minimal contamination between process steps or cross-contamination of reagents.

In some cases, for oligonucleotide synthesis application of the present disclosure, flexible 3/16″ OD FEP tubing may be used to deliver reagents to a glass lid, both of which are inert to the solvents used in the oligonucleotide synthesis. Further, as an example, a separation gap of about 0.5 mm may be implemented when delivering reagents to the top surface of the wafer with an about 150 mm diameter so that about 8 mL of reagent volume may be expected to fill the reaction chamber defined by the bottom surface of the lid and the top surface of the wafer. All chemical reagent manipulations can be controlled by an external oligo-synthesizer or an event management system, which may communicate with the reaction chamber to perform specific tasks, including but not limited to, setting up the gap distance, the amount and speed of each reagent delivery, the flow rate and duration of inert gas, etc.

In some cases, solvents used as part of chemical processing may include but not be limited to: DI water, acetonitrile (ACN), trichloromethane (TCM), and THF. The wafer can be a glass wafer. The lid can be a glass lid. The shape of the dispenser may include but not be limited to: circular and square.

In some cases, before the addition of the solutions/reagents during the chemical process, the supporting columns for the lid can be adjusted manually, mechanically, or automatically in order to make the opposing surfaces of the wafer and the lid parallel and to make the glass lid on top of the wafer centered at the central axis of the wafer.

Photo-cleavable groups (PCG) may be put on the 5′-OH group of phosphoramidite reagents. For example, compounds of Formula I may be used in oligonucleotide synthesis methods disclosed in the present disclosure:

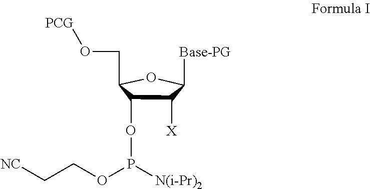

wherein PCG is a photo-cleavable group; X is H (for DNA synthesis) or a protected 2′-hydroxy group (for RNA synthesis); Base is a nucleic acid base or nucleobase including but not limited to: adenine (A), cytosine (C), guanine (G), thymine (T), and uracil (U), or analogs thereof; and PG is none, or a protecting group on reactive groups (for example, N atom or O atom) on the Base. In particular, PG may include but not be limited to N-benzoyl (Bz), N-acetyl (Ac), N-isobutyryl (iBu), N-phenoxyacetyl (PAC) and N-tert-butylphenoxyacetyl (tBPAC). Further, PCG may include but not be limited to 5′-(α-methyl-2-nitropiperonyl)oxycarbonyl (MeNPOC), 2-(2-nitrophenyl)propoxycarbonyl (NPPOC), dimethoxybenzoincarbonate (DMBOC), and thiophenyl-2-(2-nitrophenyl)-propoxycarbonyl (SPh-NPPOC), the structures of which are shown below:

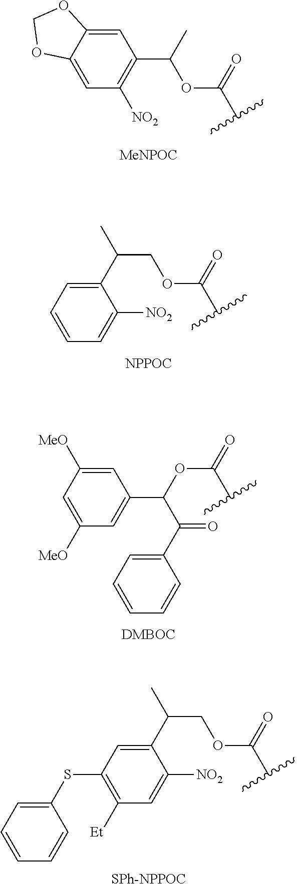

### Example 1: Probes Construction

The following is an example describing how to construct probes using the device/system/method of the present disclosure.

(1) Surface Treatment.

A substrate can be surface modified to provide primary alcohols. Any one of a variety of methods described previously, can be used (see, e.g., U.S. Pat. No. 5,959,098—“Substrate preparation process;” J. Am. Chem. Soc. 1997, 119(22), 5081—“The efficiency of light-directed synthesis of DNA arrays on glass substrates;” U.S. Pat. No. 6,262,216—“Functionalized silicon compounds and methods for their synthesis and use;” U.S. Pat. No. 8,105,821—“Silane mixtures;” U.S. Patent Pub. No. 2013165350 A1—“Surface Linkers for Array Synthesis”). For example, the substrate can be silanated by treatment with a solution comprising a mixture of N-(2-hydroxyethyl)-N,N,-bis(3-(trimethoxysilyl)propyl)amine and N-(2-cyanoethyl)-N,N,-bis(3-(trimethoxysilyl)propyl)amine (ratio from about 1:0 to about 1:20, with a total silane concentration from 1-10% w/v) in ethanol for 1-8 hours. After silanation, the silanated substrate can be rinsed with ethyl alcohol, water, and finally dried. The substrate is ready for array synthesis. In some cases, the substrate can be silicon that has been silanated with a 65 nm layer of SiO₂ layer oxidized or deposited on the surface. Other substrates, such as fused silica with suitable primary alcohol base layers can be used as well. The surface primary alcohols thus obtained can provide the anchor points for attachment to hexaethylene glycol (HEG) linker.

(2) HEG Linkage.

A DNA “chip maker” can be assembled to conduct surface chemistry on a substrate. For example, the substrate can be placed a device/system of the present disclosure, which can be connected to an automated oligonucleotide synthesizer (after replacing the conventional reaction column of the synthesizer with a device/system of the present disclosure). Then reagents can be added sequentially to the substrate surface, using standard solid-phase oligonucleotide synthesis protocols. The reagents added may include, but not be limited to, linkers such as reagents to insert a hexaethylene glycol (HEG) linker, 5′-DMT-protected-3′-O-phosphoramidites (DMT is 4,4′-dimethoxytrityl), or 5′-PCG-protected-3′-O-phosphoramidites, fluorophore-linked phosphoramidites, coupling activators (e.g., 0.5 M tetrazole in acetonitrile), or oxidizing reagents (e.g., 0.05 M iodine in acetonitrile/pyridine/water (7:1:2, v/v/v)), etc. This can be followed by a washing step by solvents, or a DMT deprotection step using trichloroacetic acid, dichloroacetic acid, or other acids in a solvent (e.g., dichloromethane) to expose the 5′-alcohol group, or a deblocking step of the PCG group on another machine using light radiation under a photolithographic mask. See, e.g., J. Am. Chem. Soc. 1997, 119(22), 5081—“The efficiency of light-directed synthesis of DNA arrays on glass substrates;” Methods in Molecular Biology, 2001, 170, 71, Rampal J B, ed.—“Photolithographic synthesis of high-density oligonucleotide arrays;” Current Protocols in Nucleic Acid Chemistry 2005, 12:12.5.1-12.5.10—“DNA Microarray Preparation by Light-Controlled In Situ Synthesis.” In this way, DNA sequences can be attached to the surface of the wafer.

Examples of automated DNA synthesizer can be, for example, Eppendorf D200 automated synthesizer, Amersham Pharmacia OligoPilot II, PE Biosystem ABI 3948 and Expedite 8909, or MerMade oligonucleotide synthesizer. Using the DNA “chip maker” the silanated substrate obtained in Step (1) with surface primary alcohols can be treated with a surface modification reagent, for example, 18-O-dimethoxytritylhexaethyleneglycol,1-[(2-cyanoethyl)-(N,N-diisopropyl)]-phosphoramidite (Glen Research Corp., Virginia, USA), followed by oxidation to make the phosphate and the removal of the DMT protecting group, to attach the phosphate diester end of the HEG linker to the surface of the silanated substrate and leave a free primary alcohol on the other end of the HEG linker.

In all DNA synthesizer-based surface chemistry conducted using a device/system according to the present disclosure, the solutions/reagents can be added via the nozzle to the top surface of the substrate when the substrate does not spin or when the substrate remains stationary relative to the lid.

(3) Oligonucleotide Synthesis.

Using the DNA “chip maker” a single PCG-protected nucleotide or DMT-protected nucleotide can be added to the primary alcohols on the substrate, depending on the need of the experiments. For example, following standard DNA automated synthesis protocols and using DMT-nucleoside phosphoramidite reagents, DMT-protected nucleotides can be sequentially added to a primary alcohol on the substrate to provide a specific DNA sequence in the end. When fluorophore attachment is desired, a PCG-nucleoside phosphoramidite, such as a compound of Formula I, can be added to the HEG linker or the previously synthesized DNA sequence. For example, a compound of Formula I, wherein the Base is thymine, the PG is none, and the PCG is MeNPOC, can be added as the last nucleotide in the HEG-linked DNA sequence on the substrate.

(4) Photo cleavage. The substrate comprising PCG-protected DNA sequence obtained in Step (3) can be removed from the DNA “chip maker” and transferred to a device for photo-lithography treatment. The substrate can be directly imaged through a photolithographic mask in a suitable mask aligner (e.g., an ABM mask aligner (ABM, Inc., Silicon Valley, Calif.)) and at the appropriate dose (e.g., about 720 mJ/cm² at 365 nm). Some PCG groups may be removed in the presence of solvent/base when radiated by light. Some PCG groups may not need the presence of solvent/base when radiated by light. In the end, a 5′-OH group on the DNA sequence can become available for the attachment of fluorescent labels.

(5) Fluorophore Attachment.

The substrate with the PCG group removed from 5′ position can be put back to the DNA “chip maker”. Using the DNA “chip maker” the free 5′OH group on the DNA sequence can react with fluorophore-bearing phosphoramidite or a mixture of fluorophore-bearing phosphoramidite and DMT-nucleoside phosphoramidite. For example, when 5′-fluorescein phosphoramidite (6-(3′,6′-dipivaloylfluoresceinyl-6-carboxamido)-hexyl-1-O-(2-cyanoethyl)-(N,N-diisopropyl)-phosphoramidite, 5′-fluorescein CEP, BA 0054, Berry and Associates) is used, a molar ratio of about 1:20 for 5′-fluorescein phosphoramidite to 5′-DMT-thymine phosphoramidite can be obtained by diluting 5′-fluorescein CEP to 2.5 mM in a 50 mM solution of 5′-DMT-T phosphoramidite in acetonitrile. Then standard DNA automated synthesis protocols can be followed to attach the fluorescein label to the DNA sequence on the substrate, followed by oxidation to make the phosphate. Other fluorophore labels can be attached.

(6) Deprotection.

The final deprotection of the synthesized, protected oligonucleotide can be done by treating the protected oligonucleotide with 50% ethylenediamine in water (v:v) for about 3 hours, rinsed in deionized water, then dried.

(7) Imaging.

All fluorescence data and images can be collected by a confocal microscope, a chip reader, a biochip scanner, or a microarray reader. For example, the substrate can be viewed with a Bio-Rad 9Bio-Rad Laboratories, Hercules, Calif.) MRC-1024 laser scanning confocal microscope using an appropriate wavelength as the excitation source, an appropriate bandpass filter in front of a photomultiplier tube to collect the emission from the fluorophore, e.g., fluorescein. Images may be acquired using direct-mode and/or time-domain Kalman filtering of image frames. In some cases, the images can be taken by a KEYENCE microscope (KEYENCE Corp. of America, Itasca, Ill.). In some cases, the fluorescence imaging can be performed on dry substrates, in fluorescein excitation/emission channel. Each image may allow exposure for about 1 second in the high resolution mode. All images to be analyzed can be taken at 40× magnification. After the solution/reagent is dispersed onto the surface of the wafer, capillary force spreads the solution/reagent over the surface of the wafer. In some cases, the wafer does not require spinning during the addition of the solutions/reagents. In some cases, additional addition of solutions/regents happens at least 80 seconds after the completion of the addition of the solutions/reagents.

### Example 2: Probe Construction Using Flow-Cell

The same procedure in Example 1 is modified to use a flow cell instead of the device/system of the present disclosure for probe construction. Flow cells can be constructed according to published procedures, for example, those disclosed in U.S. Pat. Nos. 8,241,573 and 8,778,849. Oligonucleotide synthesis conditions, such as, for example, reaction time, temperature, concentration of reagents, etc., can be kept the same as in Example 1, unless expressly stated otherwise. However, the method of mixing reagents during oligonucleotide synthesis on the surface of a flow cell may be different from the conditions disclosed in the present disclosure. For example, reagent mixing may be conducted ahead of supplying the mixture to the flow cells or inert gas may be bubbling through the solution within a flow cell. As a result, the flow cell may be required to adopt a vertical configuration of the wafer and rely on gravity or buoyancy to achieve mixing when the bubbles move through the solution within a flow cell. Such a configuration may prevent automation of the oligonucleotide synthesis as described in the present disclosure.

Surface treatment step for the wafer can be the same as in Example 1. HEG linkage step and oligonucleotide synthesis step can be done by a DNA “chip maker” assembled from a sealed flow-cell, which can be connected to an automated oligonucleotide synthesizer (after replacing the conventional reaction column of the synthesizer with a customized flow cell). When a flow cell reaction chamber is used, standard manipulation of the substrates can be followed when conducting surface chemistry, including shaking, turning, agitating the substrate inside the flow cell reaction chamber. Photo cleavage step can be the same. Fluorophore attachment step and deprotection step can be done by the DNA “chip maker” comprising the sealed flow-cell. Finally, imaging step can be the same.

Comparison of the images obtained in Examples 1 and 2 may display the difference in the quality and quantity of synthesized oligonucleotide using the device/system/method of the present disclosure and those of the flow-cell.

### Example 3: Image Analysis

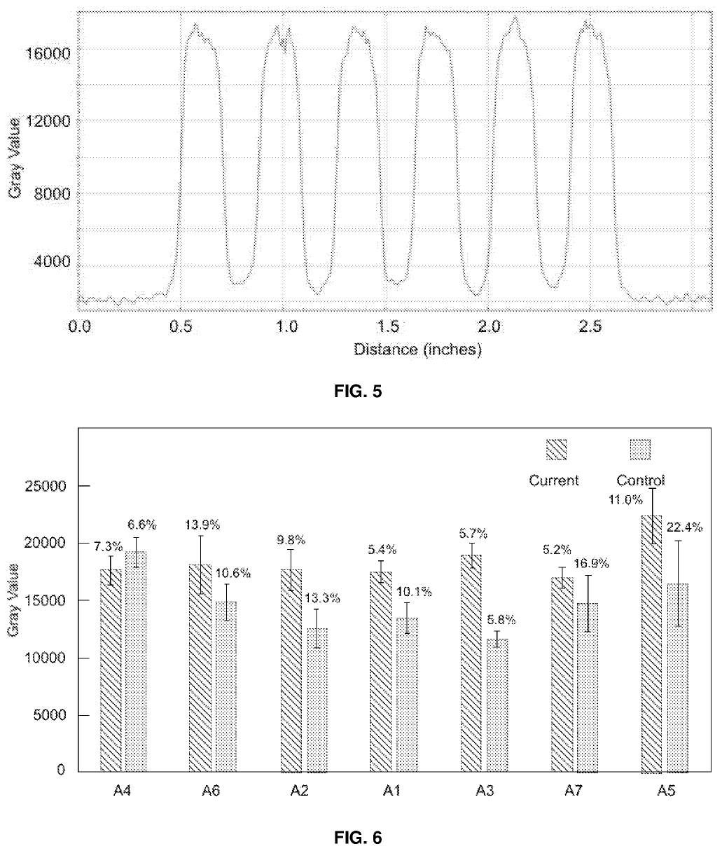

Fluorescence data for the wafers generated in Examples 1 and 2 can be collected, respectively, as images by a KEYENCE microscope (KEYENCE Corp. of America, Itasca, Ill.). FIGS. 4-5 explain the method used to take and analyze these images. As described above, images to be analyzed can be taken using a 40× objective lens on the microscope.

Turning now to FIG. 4, a wafer 400, which may be prepared according to Examples 1 or 2, is shown in an example diagram. Along the center axis of the wafer 400, five areas 402-1, 402-2, 402-3, 402-4, and 402-5 can be chosen, together with two areas 402-6 and 402-7 flanking area 402-1. As shown, areas 402-1, 402-2, 402-3, 402-6, and 402-7 are different sampling points across the surface of the wafer 400.

Each of the seven areas can be selected to measure signal strength recorded by the microscope. Within each area to be analyzed, five images can be taken. Taking area 402-7 for example, a magnified diagram of area 402M can be obtained, as shown in FIG. 4. Within the area 402M, five images of 404-A, 404-B, 404-C, 404-D, and 404-E can be taken as shown.

Each of the five images can be analyzed similarly Taking image 404-B for example, an example image 404M is shown in FIG. 4. There can be a plurality of features 406 in the image 404M, as shown in FIG. 4. In this example, the signals corresponding to fluorophore excitation can be converted into “gray” in a “black background.” Accordingly, an average background signal can be obtained by taking a predetermined number of readings along the “background” line 408 as shown in FIG. 4. The signals corresponding to fluorophore excitation can be based on six peaks (highest readings) along a “signal” line 410 as shown in FIG. 4, after subtraction of the background signal determined above. As shown in FIG. 4, the background line 408 can be adjacent to the signal line 410. However, other ways to select the background line 408 or background signal may be possible.

FIG. 5 presents an example graph showing six peaks thus obtained for the image 404M. After each of the six peak value has been determined, the average these peak values can be assigned to the image 404M Similar image analysis can be applied to all five images of the same area 402M. The average of signal readings (in gray value units) for the five images can be assigned to the area 402M Similar treatment can be repeated for all seven areas 402.

### Example 4: Signal Comparison

The images thus analyzed according to Example 3 can be relied upon to compare the devices/systems/methods used to conduct surface chemistry in Examples 1 and 2 as shown in FIG. 6. As used in FIG. 6, “Current” denotes the use of the wafer processing device/system/method of the present disclosure as in Example 1 while “Control” denotes the use of the standard flow-cell reaction chamber as in Example 2.

FIG. 6 is a bar graph that compares the average signal readings in seven areas (A1-A7) for the Current wafer and the Control flow-cell. These seven areas can be selected, have their images taken, and have these images analyzed according to Example 3. As shown in FIG. 6, except for area A4, all average signals of the Current wafer are higher in grey value than those of the Control flow-cell. A higher gray value for signals can represent a higher reaction efficiency of the overall chemical process of oligonucleotide synthesis when all the reaction conditions are kept the same. Because the Current wafer and the Control flow-cell can undergo identical surface chemistry conditions in terms of reaction time, temperature, and concentrations of reagents, FIG. 6 can demonstrate that the Current wafer may have higher reaction efficiency than the Control flow-cell. As used herein, the phrase “reaction efficiency” or “efficiency of the reaction” generally refers to the product yield of a chemical reaction or chemical process. The higher the reaction yield, the higher the reaction efficiency.

In addition to calculate the average readings for the five images taken within the same area, FIG. 6 also displays error bars (displayed both graphically and numerically (in percentage)) for the average readings in each area. The larger the error bar may represent more variance among the readings within the same area. Areas A4 and A6 show higher variance in the readings for the Current wafer while areas A1, A2, A3, A5, and A7 show higher variance in the readings for the Control flow-cell. Accordingly, the Current wafer may have more uniform fluorescence signals than the Control flow-cell when measured accordingly to Example 3. As used herein, the phrase “uniformity of reaction” generally refers to the degree of variation among product yields obtained from related or selected surface locations on a wafer. The higher the variations in fluorescence signals, the less uniform for the reaction(s).

Uniform fluorescence signals may reflect uniform reaction conditions and/or uniform reagent distribution on the surface of the substrate while conducting oligonucleotide synthesis. In some cases, surface wetting of the reagents/solutions may spread the liquid form in a thin uniform layer throughout the wafer/lid interface, thereby ensuring uniform reaction conditions without physical disturbance since the wafer does not spin or the wafer remained stationary relative to the lid. In short, the present disclosure may help filling the gap and covering the wafer surface in reagent. In some cases, the thickness of the thin layer thus formed on the surface of the substrate may be more uniform because the physical constraints imposed by the wafer/lid on the reaction chamber may be stricter than those in the control flow-cell. In some cases, precise parallelism between wafer/lid may be achieved by capillary action in the wetting process, thereby physically imposing the boundaries for the thin film formed on the surface of the substrate. In some cases, the reagents may wet the gap between the wafer and the lid via a capillary action, and this may reduce the engineering burden to make the gap either at precise dimensions or within tighter configuration of parallel alignment.

### INDUSTRIAL APPLICATION OF THE PRESENT DISCLOSURE

The device/system/method of the present disclosure may exhibit the following characteristics:
thin uniform layer of oligonucleotide on the surface of the wafer due to surface wetting of the reagent, thereby ensuring uniform reaction conditions for oligonucleotide synthesis;
high reaction efficiency for surface chemistry related to oligonucleotide synthesis;
uniform fluorescence signals for probes obtained from oligonucleotide synthesis;
strong fluorescence signals for probes;
easy implementation to ensure parallelism between the wafer and the lid during oligonucleotide synthesis;
cost saving due to a smaller reaction volume when compared with a flow cell configuration. The chamber volume of the present disclosure may be at least 6 times smaller than a flow cell, and 2 times smaller than a rotating spin-chamber. The reagent loss due to motion of the wafer or a spinning wafer may be reduced in the present disclosure when compared with a rotating spin-chamber configuration. One reason a flow cell or a rotating spin-chamber approaches need larger chamber volume may be to ensure movement or active mixing of reagents in the gap. The present disclosure which adopts a no-spin implementation, does not require such movement or active mixing.
less waste in reagents since less material may be lost due to spinning or other physical motions of the substrate during the oligonucleotide synthesis process, and smaller reaction chamber when compared with a flow-cell;
automatable process for handling the wafer and sealing the reaction chamber;
simplified equipment design for a stationary or no-spinning wafer during oligonucleotide synthesis; and
cost saving due to less waste in reagents and the simplified equipment design.

While preferred embodiments of the present invention have been shown and described herein, it will be obvious to those skilled in the art that such embodiments are provided by way of example only. It is not intended that the invention be limited by the specific examples provided within the specification. While the invention has been described with reference to the aforementioned specification, the descriptions and illustrations of the embodiments herein are not meant to be construed in a limiting sense. Numerous variations, changes, and substitutions will now occur to those skilled in the art without departing from the invention. Furthermore, it shall be understood that all aspects of the invention are not limited to the specific depictions, configurations or relative proportions set forth herein which depend upon a variety of conditions and variables. It should be understood that various alternatives to the embodiments of the invention described herein may be employed in practicing the invention. It is therefore contemplated that the invention shall also cover any such alternatives, modifications, variations or equivalents. It is intended that the following claims define the scope of the invention and that methods and structures within the scope of these claims and their equivalents be covered thereby.

What is claimed is:

1. A method for processing wafers, comprising:
(a) dispensing a first solution onto a first surface of a first wafer by a nozzle residing in a lid;
(b) spreading the first solution over the first surface; and
(c) reacting the first solution with a first reagent on the first surface, thereby forming a first product;
wherein the first wafer does not spin in (a)-(c).

2. The method of claim 1, wherein a separation gap between the lid and the first wafer ranges from about 20 μm to about 2.0 mm.

3. The method of claim 2, wherein the forming the first product in (c) is forming a covalent bond within a reaction chamber defined by the separation gap.

4. The method of claim 3, wherein in (b) the spreading substantially fills the reaction chamber with the first solution.

5. The method of claim 1, wherein the first solution comprises a first chemical reagent and a second chemical reagent.

6. The method of claim 1, wherein the first solution comprises a phosphorylating reagent.

7. The method of claim 1, further comprising, after (c):
(d) dispensing a second solution onto the first surface by the nozzle, thereby spreading the second solution over the first surface and forming a second product with a second reagent on the first surface;
wherein the first wafer does not spin in (d).

8. The method of claim 7, wherein the second reagent is the first product.

9. The method of claim 7, wherein the second solution comprises a third chemical reagent and a fourth chemical reagent.

10. The method of claim 1, further comprising after (c):
(d) dispersing a gas onto the first surface;
wherein the first wafer does not spin in (d).

11. The method of claim 10, wherein the gas is an inert gas.

12. The method of claim 10, wherein the gas is dispersed from the nozzle.

13. The method of claim 1, wherein the efficiency of the reaction between the first solution and the first reagent in (c) is higher than a corresponding reaction in a flow-cell.

14. The method of claim 1, wherein the uniformity of the reaction between the first solution and the first reagent in (c) is better than a corresponding reaction in a flow-cell.

15. The method of claim 1, further comprising prior to (a):
(i) moving the first wafer from a first position to a second position by a wafer conveyance robot; and
(ii) placing the first wafer on top of a vacuum chuck at the second position.

16. The method of claim 1, further comprising prior to (a):
adjusting support columns of the lid, thereby making a bottom surface of the lid and the first surface of the first wafer substantially parallel.

17. The method of claim 15, wherein the moving in (i) comprises removing the first wafer from a wafer cassette at the first position.

18. The method of claim 17, wherein the wafer cassette is configured to hold at least another wafer.

19. The method of claim 1, further comprising enclosing the first wafer, the nozzle and the lid within an inert gas chamber.

20. The method of claim 1, wherein the first reagent is a functional group bounded to the first surface.

21. The method of claim 20, wherein the functional group is hydroxyl group, amino group, carbonyl group, or carboxyl derivative group.

22. The method of claim 15, wherein the wafer does not spin at the second position.

23. The method of claim 15, further comprising after (c):
(d) removing the first wafer from the second position;
(e) moving a second wafer from the first position to the second position by the wafer conveyance robot; and
(f) placing the second wafer on top of the vacuum chuck at the second position.

24. The method of claim 23, further comprising after (f):
(g) dispensing a third solution onto a second surface of the second wafer by the nozzle, spreading the third solution over the second surface, reacting with a third reagent on the second surface, and forming a third product;
wherein the second wafer does not spin in (g).
